(19) United States
(12) Patent Application Publication
(10) Pub. No.: US 2018/0054156 A1
(43) Pub. Date: Feb. 22, 2018

(54) Solar Tracker System for Large Utility Scale Solar Capacity

(71) Applicant: Roger F. Lokey, Rocklin, CA (US)

(72) Inventor: Roger F. Lokey, Rocklin, CA (US)

(21) Appl. No.: 15/238,672

(22) Filed: Aug. 16, 2016

(51) Int. Cl. H02S 20/32; F24J 2/54; H02S 40/22; H01L 31/02; H02S 20/10; H02S 40/34

(52) U.S. Cl. CPC H02S 20/32; F24J 2/542; H02S 40/34; H01L 31/02021; H02S 20/10; H02S 40/22

(57) ABSTRACT

The present invention solar tracker system is directed to a solar tracker that includes a main platform capable of supporting a plurality of solar panels, a sub-platform, one or more support poles supporting the sub-platform and a linking mechanism that connects the sub-frame to the apex of the one or more supporting poles, wherein the linking mechanism rotates in a first axis, a second linking mechanism rotates in a second axis. The mail planar platform hosting the solar panels is encompassed with edge disrupters and spacing channels for adverse wind condition management. The system includes a solar tracker system includes a radiation sensor for determining the best tracking position for maximizing capture of solar energy. The large scale solar tracker system also includes at least two linear hydraulic actuators, each linear hydraulic actuator containing a distal end and proximal end, a rotational joint that connects the distal end of the linear actuators to the sub-platform and the proximal end to the support beam. The second embodiment of the present invention is a plurality of solar tracker apparatus specifically arranged into a large utility scale field system.

### FIELD OF THE INVENTION

The present disclosure relates to solar tracking apparatus and more specifically to a large scale solar tracking system using a plurality of solar panels controlled by a two axis tracking system utilizing a local computer system, astronomical algorithms, digital compass, digital inclinometers, solar radiance sensors, weather station, hydraulic controls, and secure wireless computer communication technology.

### STATEMENT REGARDING FEDERALLY SPONSORED RESEARCH OR DEVELOPMENT

This application is not the subject of any federally sponsored research or development.

### THE NAMES OF THE PARTIES TO A JOINT RESEARCH AGREEMENT

There have been no joint research agreements entered into with any third-parties.

### BACKGROUND OF THE INVENTION

Solar generation systems and devices for tracking the sun across the sky are known in the art. A number of existing systems use mechanical apparatuses that are designed for small scale output and constrained by a limited number of solar panels. Prior attempts to prepare large utility scale solar tracking systems were poorly designed and unreliable. The solar tracking system described in this application improves upon existing solar trackers by, among other things, utilizing a hydraulically controlled mechanical platform apparatus is designed for large utility scale solar cell mounting and support allowing high energy output, reliability, and durability of the large utility scale solar tracker.

### SUMMARY OF THE INVENTION

The present invention solar tracker system is directed to an large utility scale hydraulically-actuated solar tracker that includes a platform capable of supporting a plurality of solar panels, a sub-platform, and three or more angled support poles converging to an apex for supporting the sub-platform and a linking mechanism that connects the sub-platform to a planar platform, wherein the linking mechanism rotates in a first axis, a second linking mechanism rotates in a second axis. Further, the first axle and the second axle of the linking mechanism are disposed substantially orthogonal to each other and designed to track the longitudinal and latitudinal movement of the sun. The present invention solar tracker system gains operational intelligence and environmental awareness with the inclusion of a local computer system utilizing astronomical algorithms, digital compass, digital inclinometers, one or more solar radiance sensors, and a weather station. The local computer system utilizes software programming to analyze input data from the astronomical algorithms, digital compass, digital inclinometers, one or more solar radiance sensors, and the weather station to activate a movement system to follow the sun arc pathway at given latitude. During inclement weather conditions, the weather station at a minimum, determines the local wind velocity and direction, and by electrical communication with the local computer, adjusts the position of the planar platform surface for maximum energy production until weather conditions dictate a change in normal operational behavior. For example, when the wind exceeds a pre-determined speed which can damage solar cell panels, the movement system activates a wind load mitigation program. When it is raining, to effectively clean the solar cell panels, the movement system attains a rain clean configuration. At night, the movement system positions the planar platform in the horizontal or home stow position. Solar radiation sensors are used for determining the optimum tracking position for maximizing capture of daylight solar energy or moonlight solar energy at night. The one or more radiation sensors function to adjust solar tracking when sun energy is scattered and not direct, due to clouds or other conditions maximizing the capture of solar energy early in the morning hours and late in the evening hours when light is scattered. The large scale solar tracker system also includes at least two linear hydraulic actuators, each linear hydraulic actuator containing a distal end and proximal end, a rotational joint that connects the distal end of the linear actuators to the sub-platform and the proximal end to one of the support poles or support beams of the planar platform. The hydraulic actuators are optionally computer monitored for dynamic operational hydraulic pressures to determine if an unusual load is being imparted on the solar tracker or if a hydraulic actuator is leaking or has failed. The large utility scale solar tracker's local computer system adjusts the planar platform fitted with the plurality of solar panels by utilizing the hydraulic actuators to implement desired positions of the planar platform for day, night, maintenance, and hazardous weather positions. The linking mechanism, the hydraulic actuators, digital inclinometers and the local computer comprise the movement system. The local computer system also monitors each solar panel for its electrical output parameters and general health condition, and communicates this information wired or wirelessly for remote analysis and monitoring to a remote operations management computer system. The local computer system also downloads weather data, and utilizes the optional local weather station information to move the planar platform with plurality of solar panels into the optimal position to obtain maximum sun exposure and minimize wind propagated stress on the system. The local computer system also moves the planar platform to a particular position during non-sunlight hours. Additionally, the local computer system includes a means for preventing the planar platform from being driven past its mechanical limits.

### BRIEF DESCRIPTION OF THE DRAWINGS

Preferred features of embodiments of the present invention are disclosed in the accompanying drawings, wherein similar reference characters denote similar elements throughout the several views.

FIG. 1. is a top perspective view of the Tracker apparatus's main platform with a plurality of PV panels and showing one or more open groove vents running the length of one side, a solar radiation sensor near the center, a weather station near an corner, and a local computer.

FIG. 2. is a top perspective view of the Tracker apparatus showing in more detail the sub-platform and foundation system.

FIG. 3. is a bottom perspective view of the Tracker apparatus showing the sub-platform engaging the main platform.

FIG. 4 is a bottom perspective view of the sub-platform with foundation system and cross beam supports.

FIG. 5 is a side perspective view of a linking mechanism and hydraulic actuators cooperating between the main platform and the sub-platform.

FIG. 6 is a side perspective view showing the apex of the foundation system engaged to the sub-platform which includes a raised platform for supporting the linking mechanism and encompassing the hydraulic actuators.

FIG. 7 is a side perspective view showing the main platform angled to the left side of the Tracker apparatus with both hydraulic actuators in an extended configuration.

FIG. 8 is a side perspective view showing the mail platform angled to the right side of the Tracker apparatus with center hydraulic actuator in an extended configuration and the outer right hydraulic actuator in a retracted configuration.

FIG. 9 is a perspective view of the solid structure 2 axis gimbal-like linking mechanism.

FIG. 10 is a side perspective view showing the main platform angled to the left side of the Tracker apparatus with center hydraulic actuator in an extended configuration and the outer left hydraulic actuator in a retracted configuration.

FIG. 11 is a side perspective view showing the main platform angled to the right side of the Tracker apparatus with both hydraulic actuators in an extended configuration.

FIG. 12 is a more detail view of the weather station with wind velocity and direction monitoring apparatus.

FIG. 13 is a perspective view showing how the radiation solar sensor and local computer adjust the angle of the main platform for maximum solar efficiency when sun rays are diffuse and scattered during periods of partial or complete clouding that shields the direct sun rays.

FIG. 14 is a perspective view showing how the radiation solar sensor and local computer adjust the angle of the main platform for maximum solar efficiency when sun rays are diffuse and scattered when the sun is near the morning or night low horizon.

FIG. 15 is a perspective view with the planar platform in a wind avoidance configuration.

FIG. 16 is a perspective view with the main planar platform in a rain clean or maintenance stow configuration.

FIG. 17 is a Venn diagram graphic view of the software's operational functional modules, along with their respective core feature sets.

FIG. 18 is perspective view of square having a plurality of Trackers in a certain configuration that result in a 1 mega-watt (MW) energy production field.

FIG. 19 is a perspective cluster view of the Tracker Apparatus Management Dashboard GUI having a 1 mega-watt (MW) Cluster View of Trackers that monitors detailed electrical performance parameters.

FIG. 20 is a perspective Track view of the Tracker Apparatus Management Dashboard GUI having a 100 kilo-watt (kW) Single view that monitors the elements of electrical performance and environmental parameters.

FIG. 21 is a perspective view of the Tracker Apparatus Management Dashboard GUI showing the monitoring of critical environmental variables.

FIG. 22 is a perspective view of the Tracker Apparatus Management Dashboard GUI showing the monitoring of critical hydraulic variables.

FIG. 23 is a perspective view of the Tracker Apparatus Management Dashboard GUI showing the monitoring of critical hydraulic oil variables.

FIG. 24 is a perspective view of the Tracker Apparatus Management Dashboard GUI showing the precise monitoring of the main platforms position.

### DESCRIPTION OF THE PREFERRED EMBODIMENTS

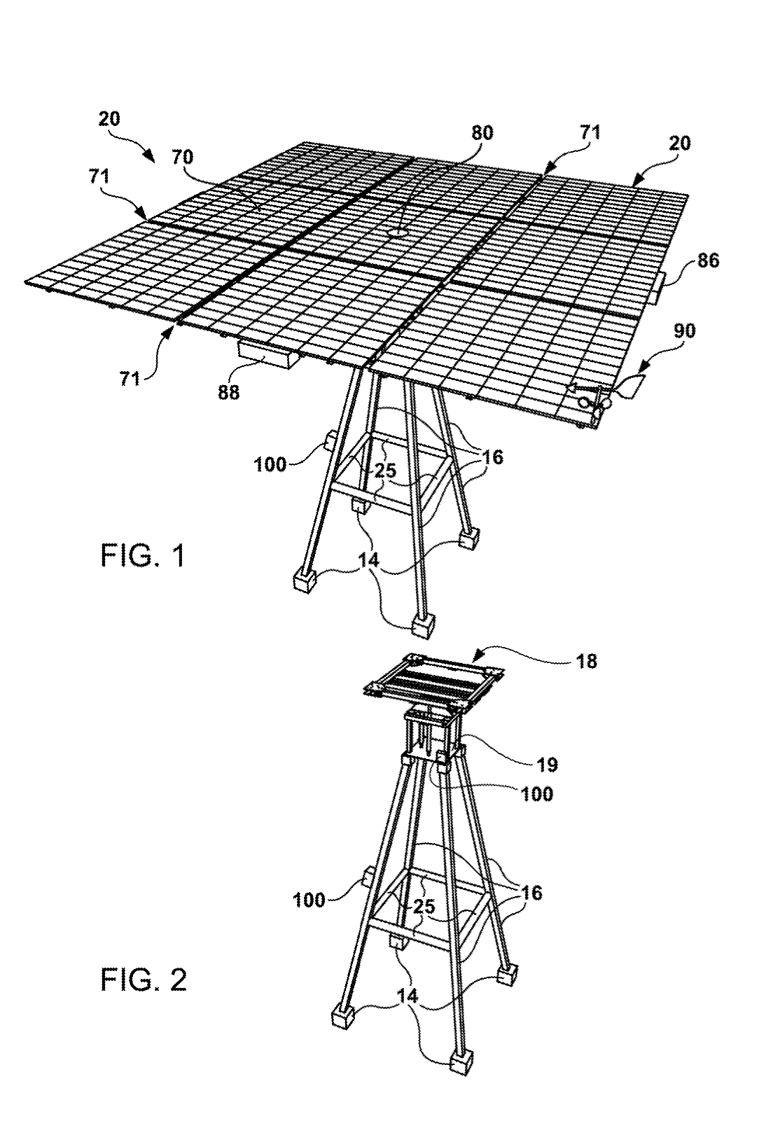

FIG. 1 is a perspective view of the present invention improved solar tracker for utility scale solar cell capacity including support structure, a mounting pole, hydraulic actuators, 2 axis gimbal mechanism, planar platform for mounting the plurality of solar cells and including a digital compass, digital inclinometers, solar radiation sensors, weather monitoring station and computer wireless and/or wired electronic communication technology.

The present invention will now be described more fully hereinafter with reference to the accompanying drawings, in which preferred embodiments of the invention are shown. This invention may, however, be embodied in many different forms and should not be construed as limited to the illustrated embodiments set forth herein.

In the following description, like reference characters designate like or corresponding parts throughout the figures. Additionally, in the following description, it is understood that terms such as “first,” “second,” and the like, are words of convenience and are not to be construed as limiting terms.

The embodiments of the present invention are directed to one or more Tracker apparatuses 10 for focusing or aiming the plurality of photovoltaic “PV” cells 60 such that the Tracker's sub-platform 18 and planar main platform 20 are positioned to optimize the capture of energy from the sun for conversion into electricity or other useful forms of energy. The embodiments of the present invention are optimized for solar panel volumes, strength, reliability, efficiency and maintainability. The embodiment also includes a solar radiation sensor 80 on the platform for re-aiming the plurality of PV cells 70 and to reposition and optimize the capture of solar energy when the sun rays are not direct but diffuse, when clouds partially or completely shield the direct sunlight, and when the sun is near the morning or night horizon. The plurality of PV cells 70 are standard PV solar panels fabricated from manufacturers such as Bosch, PB solar, Canadian Solar, China Sunergy, Conergy, DelSolar, Evergreen Solar, First Solar, Kyocera, Mitsubishi Electricity, Panasonic, Schott Solar, Sharp, SolarPark, SolarWorld, SunPower, and/or Suntech, or any other appropriate solar panel manufacturer. The plurality of PV cells 70 are easily replaceable on the Tracker Apparatus 10 so that when one of more PV cells 70 fail, become defective, or lose electrical efficiency. Furthermore, entire series of PV cells 70 can be easily be replaced on the Tracker Apparatus when new more efficient PV cells become available on the market and the user wants to upgrade to the newer PV cells that offer advantages of higher sunlight conversion efficiency. The mounting of the PV cells 70 to the main platform are attached by a custom “T” rail that runs substantially alone the length and width of each PV cell such that the removal of PV cell only requires the removal as few attachment means whereby the entire “T” rail is removed, releasing one entire side of the PV cell 70.

The main platform 20 is shown have a plurality of wind gaps 71 along the length of the sides of and crisscrossing the mail platform 20 which functions to reduce the effects of wind on the main platform 20 with PV cells 70. Also shown are a solar radiation sensor 80 located near the center of the PV cells. Also shown is an optional digital inclinometer 86 and an optional digital compass 88. A weather stations 90, shown in an enlarged format, is shown near one corner. A local computer 100 is shown attached to one of the support poles 16. It is anticipated by the Applicants that the solar radiation sensor 80, optional digital inclinometer 86, optional digital compass 88, the weather station 90, and the local computer 100 can be located in various other locations in close proximity to the main platform 20. Also protruding down from the main platform 20 is one or more support poles 14 with supporting cross-beams 25 and footings shown as solid blocks. It is anticipated that the footing can using other anchoring technology such as helical screws, embedded poles, concrete pads with attachment means. The choice of footing will be dictated by the soil conditions where the Tracker apparatus 10 will be located.

A digital compass 84 and digital inclinometer 86 will be used to accurately position the large main platform 20 defined by the local computer 100. The digital compass 84 is a stable format with high resolution for locating the main platform in a very accurate direction. Digital compass like the Honeywell PC based HMCS883L equipped with magneto sensors provides compass accuracy of 1° to 2°. Other manufactures are fabricated other PCB based digital compasses that can be used with the present invention. The digital inclinometer is an instrument for accurately measuring the scope or tilt of the main platform 20. Two axis MEMS inclinometers can be precisely calibrated for non-linearity for operating temperature variation resulting in higher angular accuracy over wider angular measurement range. Two-Axis inclinometer, with built-in accelerometer sensors, may generate numerical data tabulated in the form of vibration profiles enable Tracker apparatus 10 to track and assess alignment quality in real-time and verify structure the positional stability.

In addition, the Tracker apparatus includes a weather station 90 that monitors wind, rain, sun and other environmental variables. Optionally, the hydraulic actuators 24, 26 of the Tracker apparatus 10 can include a pressure sensor 48 for monitoring the condition of the hydraulic system. Furthermore, the Tracker apparatus 10 includes a local computer 100 that communicates wireless and/or wired electronic communication technology to a remote operations management computer or station 110. The local computer 100 is in electrical communication with the optional hydraulic sensor 48, the one or more solar radiation sensors 80 and the weather station 90. The local computer 100 has local control of the Tracker apparatus 10 to automatically respond to environmental and emergency conditions, such as when wind exceeds a defined threshold, or when the solar sensors detect that a modified position of the solar cells would produce more electrical energy.

As depicted in FIG. 1, in an embodiment of the present invention, the Tracker apparatus 10 includes a three or more support system 12 comprising an series of round members, I-beam cross members, T-cross or similar structural members 14 with foundation mountings 16 (such as screws, concrete or metal foundations) that secure the series of round members, I-beam cross members, T-cross or similar structural members 12 forming the three or more pole structure with angles such that the distal end of the three or more poles meet at an apex 21 that engages the sub-platform 18 to which the large planar platform 20 securing the plurality of solar cell panels is affixed. The support system 12 is comprised of a round member, I-beam cross member, T-cross or similar structural members 14 and a plurality of removable, adjustable foundation mountings 16 (pilings, ground screws, helical ground anchors, or the like). In another embodiment of the present invention, the foundations can be affixed to a large concrete slab. In this embodiment the foundation system 12 comprises a concrete slab with adjustable mountings. This system provides for rapid and inexpensive installations while also providing for inexpensive foundation system 12 that lasts for fifty years of service. The foundation mountings 16 may be adjustable or non-adjustable as needed by atmospheric environmental conditions. The support system 14 can have a series of cross members 17 to serve to provide rigidity for the three or more support poles structures. It is anticipated by the Applicant that multiple series of cross members 17 can be strategically located and engaged to the three or more support poles 14 for increasing the strength and rigidity.

The round members, I-beam cross members, T-cross or similar structural shapes forming the one or more support pole structures 14 are preferably fabricated from a metallic corrosive resistant material such as that defined in ASTM A588 steel which defines a high-strength, low-alloy structural steel with atmospheric corrosion resistance. It is anticipated by the Applicant the components of the round members, I-beam cross members, T-cross or similar structural shapes forming the one or more support tubes, or other components of the Tracker apparatus 10, can be fabricated from a Series 300 stainless steel, (e.g. 304, 316), a cement composition, or high-strength polymeric material. Connected to the series of round members, I-beam cross members, T-cross or similar shapes forming the three or more support tubes 14 are two linear hydraulic actuators 24, 26 and a central post section 21. The first linear hydraulic actuator 24 is preferably designed to cause substantially east-west facing movement and the second linear hydraulic actuator 26 is preferable designed to cause substantially north-south movement. The bottom end of the linear hydraulic actuators 28, 30 are distally rigidly connected to the round members, I-beam cross members, T-cross or similar shapes forming the three or more support tubes 14 via bolt and screw, adhesive technology or other connection technology 32 but may optionally include a flexible movement joint mechanism 34, 36. The top end of the linear actuators 38, 40 are proximally connected to the sub-platform 18 with proximal with joint mechanism 42, 44 using bolt and screw, adhesive technology or other connection technology 46. These proximally located joint mechanisms 38, 40 allow the linear actuators 24, 26 to achieve two degrees of freedom of movement, to relieve strain in the linear actuators, assuring proper, free motion of the actuators. The two degrees of freedom refers to a movement that can cause motion in two independent forms such as two orthogonal axes or two orthogonal lines of motion. In the preferred embodiment of the invention shown in FIG. 2, the bottom end 22 of the three or more support poles are rigidly anchored to the foundation system 12 where the top end of the support poles 23 converge into an apex 21 which supports a linking mechanism 50. The top end of the linear actuators is connected to a sub-platform 18, which holds a main solar cell panel platform 20 that tracks the sun. The main solar cell panel platform 20 is designed to engage and mount a plurality of typical solar cell panels 70. The linear actuators 24, 26 are connected to the sub-platform 18 via a top end joint mechanism 38, 40, and the rigid bottom end connections (or optional bottom end joint mechanism 34, 36) that allows the actuators 24, 26 to achieve two degrees of freedom of movement to relieve any stress forces and assure proper positioning. The linear actuators 24, 26 also function as structural members when not in motion.

The three or more support pole structure 14 coalesce into an apex structure 21 that is connected to the sub-platform 18 via a two axis gimbal-like linking mechanism 50 that allows the sub-platform 18 and the main platform 20 to rotate around the apex structure 21 with two degrees of freedom.

FIG. 2. demonstrates a top perspective view of the Tracker apparatus 10 showing in more detail the sub-platform 18 and foundation system consisting of one or more support poles 14, a one or more footings 16, and some optional cross-beam structures 25. The three or more poles 14 are angles and meet at a proximal apex and engaged to an apex platform 19, The local computer 10 is a shown in various other positions, such as attached one of the poles or on the apex platform 19.

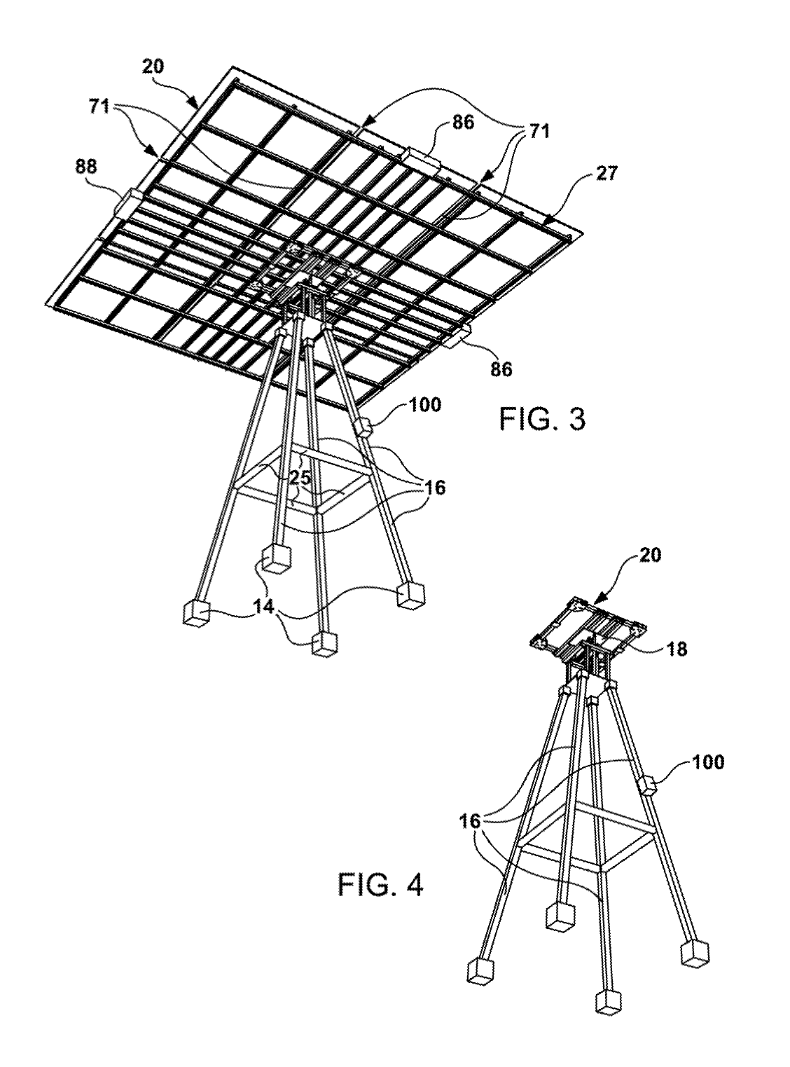

FIG. 3. demonstrates a bottom perspective view of the Tracker apparatus 10 showing the sub-platform 18 engaging the main platform 20. Extending below are the foundation system consisting of one or more support poles 14, a one or more footings 16, and some optional cross-beam structures 25.

FIG. 4 is a bottom perspective view of the sub-platform with foundation system and cross beam supports with footings. As stated before, protruding down from the main platform 20 is one or more support poles 14 with supporting cross-beams 25 and footings shown as solid blocks. It is anticipated that the footing can using other anchoring technology such as helical screws, embedded poles, concrete pads with attachment means. The choice of footing will be dictated by the soil conditions where the Tracker apparatus 10 will be located.

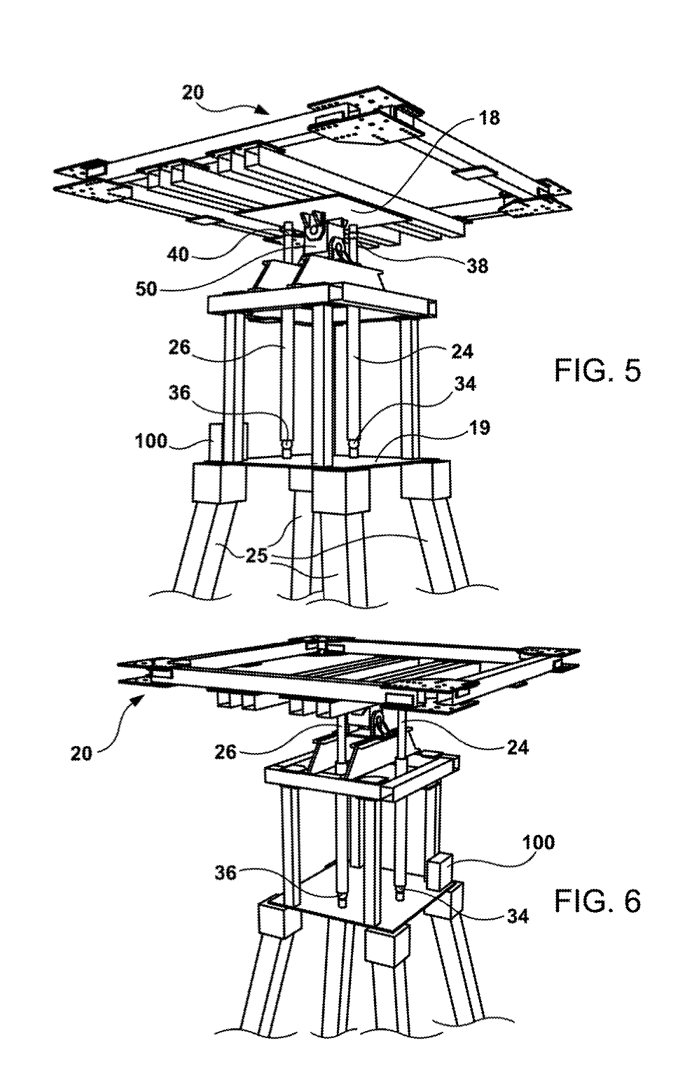

FIG. 5 is a side perspective view demonstrating in more detail the two axis gimbal-like linking mechanism 50 and hydraulic actuators 24, 26 cooperating between the main 20 platform and the sub-platform 18. Due to the length needed for the hydraulic actuators 24, 26 to retract and extend, a raised platform is constructed above the apex platform 19. The main platform skeleton structure is shown with cross bars and corner parts.

FIG. 6 is a side perspective view showing the apex platform 19 of the foundation system engaged to the sub-platform 18 which includes a raised platform for supporting the linking mechanism 50 and encompassing the hydraulic actuators 24, 26. The local computer 100 is show in the optional position sitting on the

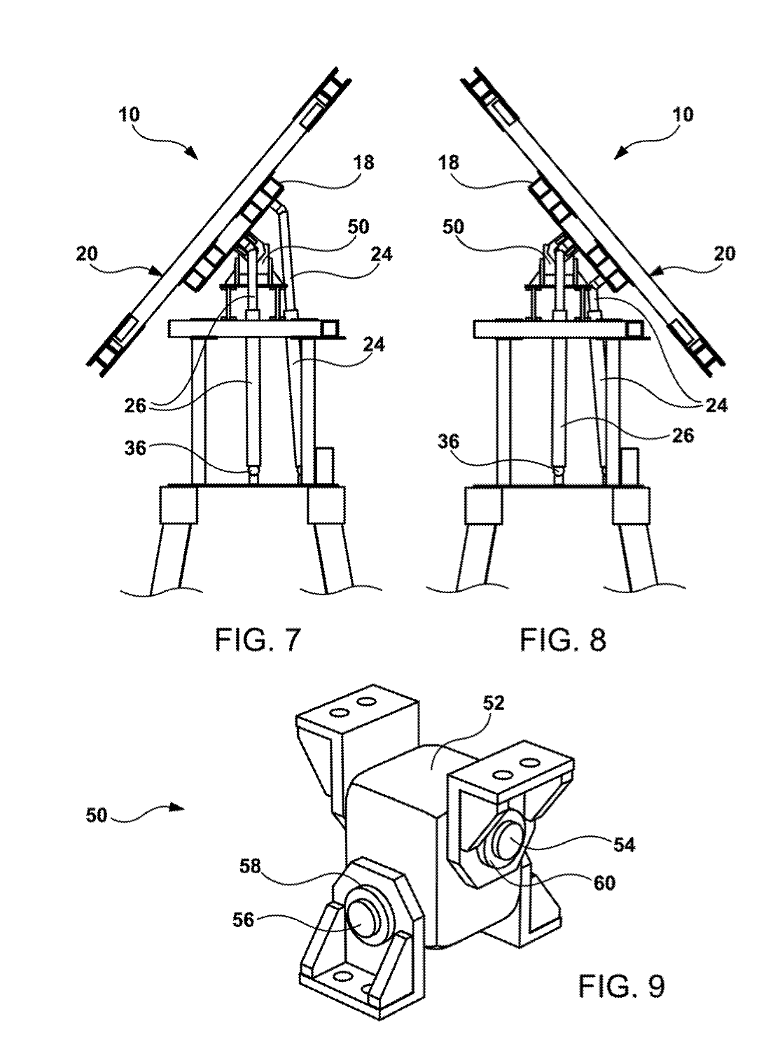

FIG. 7 is a side perspective view showing the main platform 20 angled to the left side of the Tracker apparatus 10 with both hydraulic actuators 24, 26 in an extended configuration. The top end 38 of center hydraulic actuator 26 shows a flexible joint 42 and top end 30 of outer hydraulic actuator 24 shows a flexible joint 44 that reduces stress on the attachment and associated hydraulic actuators. Correspondingly, the bottom end 28 of center hydraulic actuator 26 shows a flexible joint 34 and bottom end 30 of outer hydraulic actuator 36 shows a flexible joint 44 that reduces stress on the attachment and associated hydraulic actuators.

FIG. 8 is a side perspective view showing the main platform 20 angled to the right side of the Tracker apparatus 10 with center hydraulic actuator 26 in an extended configuration and the outer right hydraulic actuator 24 in a retracted configuration. The top end 38 of center hydraulic actuator 26 shows a flexible joint 42 and top end 30 of outer hydraulic actuator 24 shows a flexible joint 44 that reduces stress on the attachment and associated hydraulic actuators. Correspondingly, the bottom end 28 of center hydraulic actuator 26 shows a flexible joint 34 and bottom end 30 of outer hydraulic actuator 36 shows a flexible joint 44 that reduces stress on the attachment and associated hydraulic actuators.

As shown in more detail in FIG. 9, a two axis gimbal-like linking mechanism 50 is mounted at the top of the three or more support pole axis 21 and engages and attaches to the sub-platform 18. Preferably for flexibility, moving joints at the top and bottom of each hydraulic actuator 24, 26 are attached at an angle to optimize use of the linking mechanism 50 within their mechanical limits. Flexible joints at the tops and bottom of the actuators 24, 26 can optionally have some rotational freedom in addition to what is provided by the free rotation of the actuators 24, 26.

Also shown in more detail in FIG. 9, a two axis gimbal-like linking mechanism 50 has a defined configuration such that it provides a shoulder 52 for which limits the main platform 20 from moving past a given angle. The two axis gimbal-like linking mechanism 50 at the top of the apex structure 21 is designed to be sufficiently strong to withstand very large torque forces resulting from the weight of the main platform with plurality of solar cells, in a moment from the center axis point. The linking mechanism 50 includes a body member 52 that connects a first axle 54 and a second axle 56. The first axle 52 and second axle 56 preferably include bearing assemblies 58, 60, 62, and 64 that are mounted orthogonal to each other to allow the linking mechanism 50 to achieve a two degree of freedom movement. In the preferred embodiment, the linking body member 52 is fabricated from a strong metallic or cement material with incorporated rigidity members. In addition, the first axle 54 and the second axle 56 can be fabricated from a strong metallic material, such as A588 steel, or series 300 stainless steel. The axle bearing assemblies 58, 60, 62, and 64 are preferable fabricated from bronze metallic material. The bronze bearing 58, 60, 62 and 64 provide a long lasting lubricious surface for the metal axle 54, 56 which requires little or no additional lubrication. The linking mechanism 50 is designed to include an offset that acts to assure the sub-platform 20 has sufficient clearance past the three or more support poles 14 and apex structure 21 when the main platform 20 angle is close to the horizon. The fabrication materials and structure is designed to provide minimal strain displacement even under heavy wind loads. However, under extreme wind conditions, the weather station which, at a pre-determined of a wind velocity and direction sensor sensing, will direct the local computer 100 to attain a wind avoidance configuration or the horizontal weather configuration.

The orientation of the two axis linking mechanism 50 at the apex 21 of the three or more support post structures 14 is fixed and capable of resisting rotational forces about its center axis. The three or more support post structure 14 itself is also designed to be capable of resisting such rotational forces transferred from the linking mechanism 22. This resistance keeps the solar tracking apparatus 10 standing erect and in calibration.

Furthermore, the mounting of the two axis linking mechanism 50 at the apex 21 of the three or more support post structure 14 at the top of each actuator 24, 26 is at an angle to optimize use of the linking mechanism 50 or joint within their mechanical limits. Positioning the lower joint or fastened connection to be high in relation to the foundation is desirable as it improves stability and strength of the solar tracking apparatus for certain angles of the east-west degree of freedom at the beginning and ending of solar days. Additionally, the high positioning of the hydraulic actuators 24, 26 helps reduce strain and interference, allowing the solar tracker apparatus 10 to efficiently reach angles required to align the main platform 20 (and sub-platform 18) orthogonal to the rays of the sun. The joint members at the top and bottom of the actuators 24, 26 can optionally have some rotational freedom in addition to what is provided by the free rotation of the actuators 24, 26.

Each Tracker apparatus 10 is self-sufficient as to its core software functionality. Each tracker will have a unique ID and supporting database record structure for performance history. While indexed within a Cluster by an identification number, it is a stand-alone device making it always directly addressable. The solar tracking apparatus 10 is designed for rapid cost effective deployments and scalability. The assembly process is aided by the specific system design in such that multiple assembly steps can take place simultaneously to assemble the components. Simultaneous operations culminate in final assembly wherein a crane (or similar) is used to place the components so that they can be fastened together efficiently. All electronic components in the system are provided with an enclosure for protection from weather and the like.

In one embodiment, shown positioned near the center of the plurality of solar cell panels 70, is the one or more solar radiation sensors 80, a digital compass 84, and a digital inclinometer 86. It is anticipated by the Applicant that the one or more solar radiation sensors 80, the digital compass 84, and the digital inclinometer 86 can be placed in other locations in close proximity to the solar cell panels 70. The one or more solar radiation sensors 80, the digital compass 84, and the digital inclinometer 86 are in secure wired or wireless electronic communication with the local computer 100 and function to modify the typical sun arc pathway when the sunlight is not in a direct ninety degree angle to the solar panels 70, but rather is scattered or diffuse due to such situations as cloudy conditions or in the morning and evening hours when the sun is low in the horizon, and sunlight is not aimed directly at the solar panels. By using the monitored maximum solar radiation measurement from the solar radiation sensor 80, the local computer 100 modifies the angle of the solar cell platform 20 such that maximum radiation for the plurality of solar cell panels 70 is obtained. It is known that correcting for low horizon conditions, increases the effectiveness of capturing that radiation, thereby increasing tracker efficiency by approximately ten percent or more. The one or more solar radiation sensors 80 monitor the solar radiation and communicate with the local computer 100 to make real-time corrections. So when scattered clouds obscure the sun periodically, the solar radiation sensors 80, together with the local computer 100, can make appropriate corrections in the platform 20 angle to maximize capturing solar radiation resulting in a maximum solar capture configuration 82. Some manufactures of solar radiation sensors 80 are Apogee Instruments located in Logan, Utah and Davis Instruments located in Hayward, Calif.

In another embodiment, the MLD (maximum light detection) principle relies on tracking the solar module to the most energetic solar point in a manner that is as quick, precise, and as energy-saving as possible. This is a function of the control module, an acrylic pyramid (tetrahedron) with an edge length of 80 millimeters.

The control module continually measures the intensity and angle of incoming light beams and aligns the solar module platform accordingly. The module takes account not only of the radiation from the sun, but also light reflected by snow, water or light-colored rock or diffused radiation that penetrates clouds.

Two sensor cells provide reference values, which are processed and evaluated by the integrated logic chip of the control module. A differential amplifier controls the transition from the logarithmic characteristic curve during strong radiation to a linear characteristic curve during low currents, as caused by diffuse light. Because of this, the systems produce a relatively high yield, even with weak radiation. For the linear characteristic curve, the logic chip accepts a much higher value than for the logarithmic curve. This results in a significant increase in the readjustment precision with decreasing brightness. The differential voltage is additionally impinged with a load, whereby the shutdown threshold is extended up to some 30 watts per square meter, and thus into twilight conditions.

A third sensor cell on the rear of the control module ensures that the solar cell platform automatically faces the sunrise in the morning. To prevent both hydraulic drives from moving at the same time in dual-axis systems, sensor control system is designed so that the east-west drive has priority over the elevation. Each dual-axis tracking system could be equipped with one or more control modules.

Because of the automatic tracking of each individual system, which is a special feature of the present invention compared with astronomically guided tracking utilizing a central control system, as well as wiring up the solar farm with data cables, is not necessary. This has considerable effect on the cost effectiveness of solar farms. With varying and quickly changing cloud conditions, for example, the present invention control modules always independently move each tracker system in the entire solar farm deployment to the optimum solar energy collection position. This means that each unit achieves the highest possible energy yield.

There is also a safety aspect. If the on-board tracker sensor control should fail, it is always just one system that is involved as the other units in the solar farm deployment continue working normally.

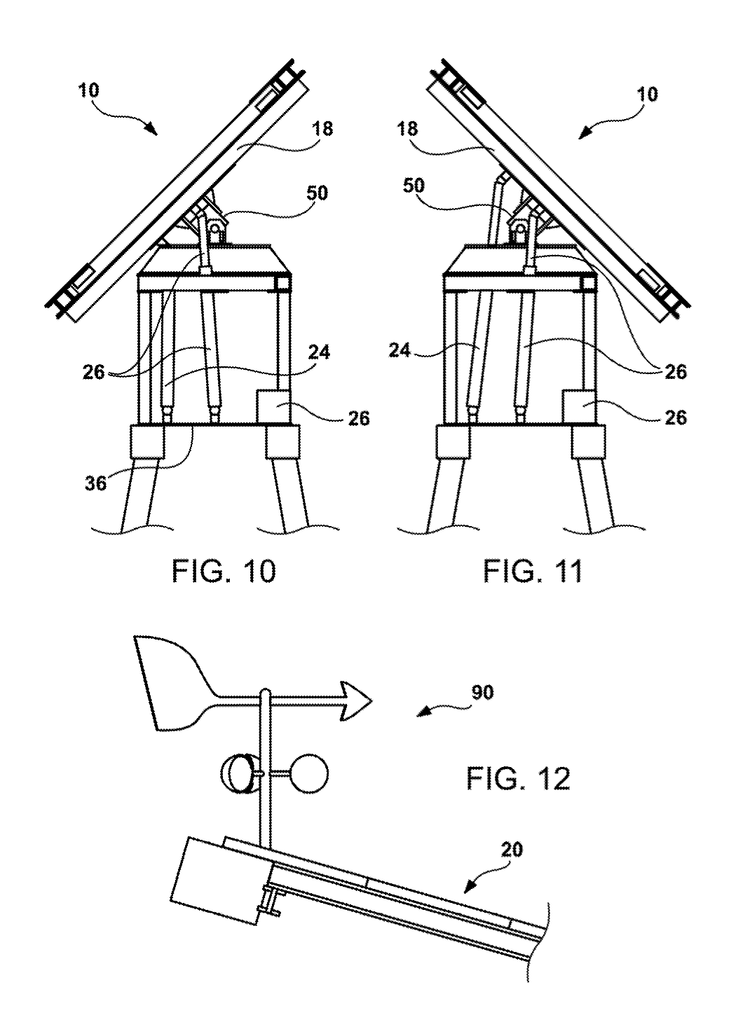

FIG. 10 is a side perspective view showing the main platform 20 angled to the left side of the Tracker apparatus 10 with center hydraulic actuator 26 in an extended configuration and the outer left hydraulic actuator 24 in a retracted configuration.

FIG. 11 is a side perspective view showing the main platform 20 angled to the right side of the Tracker apparatus 10 with outer hydraulic actuator 24, and center hydraulic actuator 26 in an extended configuration.

FIG. 12 shows a more detail view of the weather station with wind velocity and direction monitoring apparatus. Shown near the side of the plurality of solar cell panels is the weather station 90. It is anticipated by the Applicant that the weather station 90 can be placed in other locations in close proximity to the solar cell panels 70. The weather station is in wired or wireless electronic communication with the local computer 100 and functions to modify the main platform 20 when environmental conditions warrant. The weather station 90 has a wind monitor that measures the wind velocity and angle on a real time basis. This information is communicated electronically to the local computer and if the programmed software senses that the wind velocity exceeds a given value, the main platform 20 can be positioned in a defensive configuration to minimize damage to the system. The weather station 90 can also monitor the local ambient temperature, barometric pressure and humidity. The weather station 90 also may have an electronic communication means with the internet and weather satellites to download weather data and information that might be useful for the Tracker apparatus 10 to modify the are and angle of the main platform 20 in response to environment conditions.

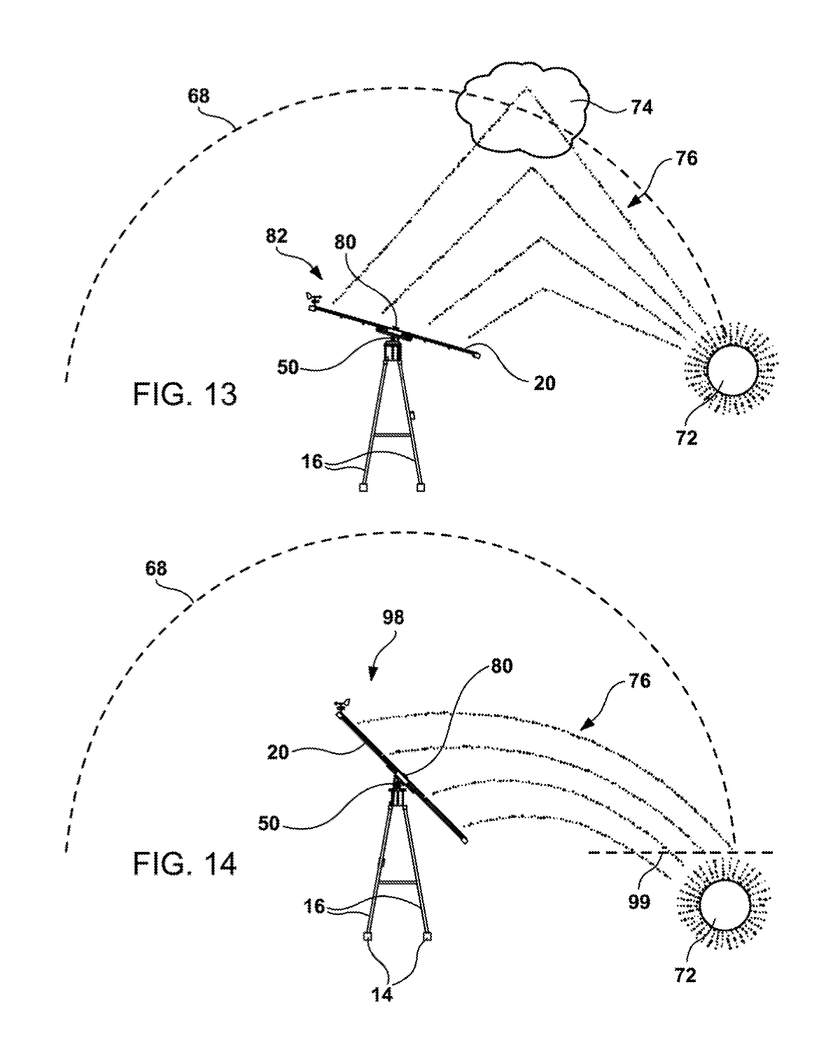

FIGS. 13 and 14 show a perspective view typical sun arc pathway 120 showing the advantage of the present invention solar radiation sensor technology 80 improving the efficiency of solar absorbance when sunlight is scattered and diffuse during periods of partial or complete clouding that shields the sunlight, or when the sun is near the morning or night low horizon. Using the solar radiation sensor 80 to modify the typical sun arc pathway when the sun light is not in a direct ninety degree angle to the solar panels 70, but rather is scattered or diffuse due to such cloudy conditions or during the morning and evening hours when the sun is low in the horizon, and sunlight is not aimed directly at the solar panels. By using the monitored maximum solar radiation measurement from the solar radiation sensor 80, the local computer 100 modifies the angle of the main platform 20 such that maximum radiation for the plurality of solar cell panels 70 is obtained. It is known that by correcting for low horizon conditions, an increase in the efficiency of capturing the radiation during these periods, an increase in the efficiency is approximately ten percent. The solar radiation sensor 80 monitors the solar radiation and communicates with the local computer 100 to make real-time corrections. So when scattered clouds obscure the sun periodically, the solar radiations sensor 80 together with the local computer 100 can make appropriate corrections in the main platform 20 angle to maximize capturing solar radiation resulting in a maximum solar capture configuration 82.

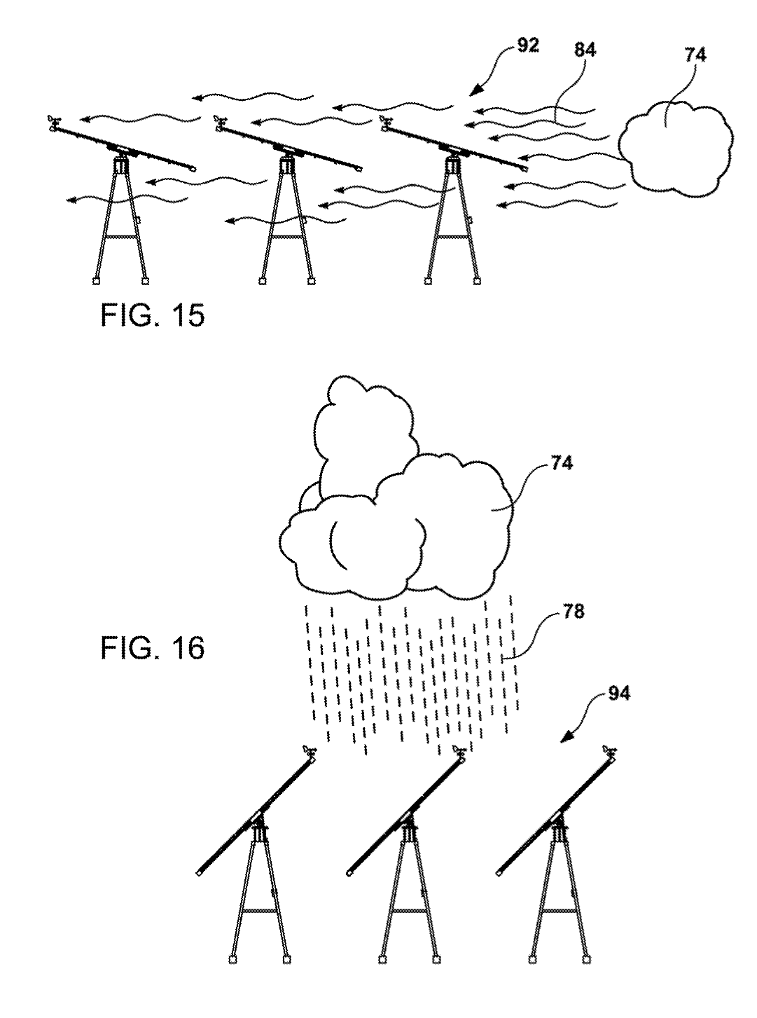

Shown in FIG. 15 is a perspective view with the main platform 20 in a wind avoidance configuration 92. In this wind avoidance configuration 92, the local computer 100 reads the wind speed and direction from the weather station 100 and positions the main platform 20 with the plurality of solar cell panels into the wind (with the front glass surface of solar cell panels 70 facing the wind) which is then tilted into the wind so that the main platform 20 with plurality of solar cells 70 is angled down in a range of 2-18 degrees and in a more specific range of 5-8 degrees from the horizontal axis and into the wind.

In extreme conditions, the main platform 20 with plurality of solar cells 70 may be positioned in a flat horizontal configuration 96. There exist edge disrupters along the perimeter edges of the planar platform with the plurality of solar panels, with the expressed purpose to disrupt wind flow across the planar platform, defeating wind pressure buildup. There is designed channel spacing within the arrangement of mounted solar panels, which bleed off wind pressure buildup during variable or sustained periods of extreme weather conditions. The weather station will regularly update the local computer on relevant conditions, such that the local computer will analyze conditions-over-time to properly determine the correct next action(s) given current time-of-day.

The weather station 90 can predict from downloaded weather data or may also have a moisture/water sensor such that when the plurality of panels is exposed to rain conditions, the local computer 100 instructs the movement system to rain wash configuration 94 which will range from 40 to 48 degrees from the horizontal axis (See FIG. 16). Solar cell panels 70 do collect dust and dirt on the glass surface so a periodic washing maintains their solar capture efficiency. But once cleaned, additional washing will have little effect on the efficiency, so the weather station wired or wireless electronically communicates with the local computer 100 which has algorithms and software instructions to only enter the rain clean configuration when it is necessary, or when opportunistic conditions warrant. Optionally, an optical sensor can be utilized to measure the amount of dirt and debris on the glass covering of the solar cell panels 70 to better understand efficiency degradation, thereby triggering software instructions to hunt for the next potential rain wash configuration opportunity.

A maintenance configuration 94 is similar to the rain wash configuration but this is selected by a hard or soft button, switch, or other technology that causes the movement system to enter a range from 38 to 50 degrees, and more specifically from 40 to 48 degrees from the horizontal axis for maintenance, repair, replacement or other corrective action associated with the solar cell panels 70. The hard or soft button, switch, or other technology causing the movement system to become active can be located on the local computer 100, the remote operations management computer 110 or both.

The local computer 100 is in secure wired or wireless electronic communication with the one or more solar radiation sensors 80, the weather station 90, the digital compass 84 and the digital inclinometer 86. The local computer 100 is also in secured wired or wireless electronic communication with a remote operations management computer 110. The local computer is located near and engaged with the one of the structural support poles 14. It is anticipated by the Applicant that the local computer 100 can be placed in other locations in close proximity to the solar cell panels 70. The local computer can have a display 112 and a keyboard 114 for an individual to review parameters for the tracker apparatus 10, the solar cell panels 70, or the hydraulic actuators 24, 26 or for download or upload software instructions. The local computer 100 take information from timing, sensors and environment variables and can send commands to change the angle and configuration of the main platform of the Tracker Apparatus.

The Tracker apparatus 10 will utilize inputs from the defined location, time of day, date, GPS coordinates, digital compass, digital inclinometers, solar radiation sensors, environmental sensors, known astronomical solar calculations, and foundation orientation to govern the movement control system. The local computer 100 will use these inputs and/or calculations to acquire several sets of solar position angles for a given time and day. The local computer 100 will have programmable software instructions to perform the designed operational characteristics for controlling the movement control system. There are several operational stowing (STOW) positions required, so these are defined below. Most refer to a physical resting position for the Tracker's Array Table.

HOME STOW—normal, nighttime resting position that expect to find Trackers at end-of-service-day. Defined as 0° Pitch (Y-axis) and 0° Roll (X-axis) parallel to the ground.

EMERGENCY STOW—action used to describe the condition where immediate movement back to HOME STOW position is mandated. Typically triggered by an adverse weather situation, that is emerging unrelentingly.

Assume action results in a HOME STOW orientation reached within a few minutes to minimize a rapid wind pressure change, without incurring damage to the Tracker's PV panels, hydraulics or support structure.

WEATHER STOW—pitched position reached after re-zeroing to HOME STOW orientation to defeat wind pressure buildup. Would typically be in a “pitched down” position, several degrees into the direction of an emerging weather condition, typically seen as high winds. Pitched directional orientation to be updated over time as the conditions warrant.

MAINTENANCE STOW—this is a triggered condition by on-site personal's need to perform either scheduled or unscheduled Tracker maintenance. Tracker in “off-line” condition.

Typical situations would be panel cleaning, replacement, or wiring diagnostics.

These would cause Array Table to be positioned at a 48° maximum downward tilt in the appropriate quadrant needing attention. Array resting on any two (2) legs.

Could also be a “stand-down” condition when maintenance service cycle exceeds a daytime work day, so Tracker unusable until further notice.

OPERATIONAL DAY—normal, nighttime resting position that expect to find Trackers at.

PRODUCTION DAY—normal, nighttime resting position that expect to find Trackers at.

The movement control system can make use of polynomial spline curves, data tables, solar calculation in real time, or series of rules combined with actuator positions translated from standard elevation and azimuth angles, that are adjusted by the one or more solar radiation sensors and environmental sensors, to drive the linear actuator 24, 26 positions. In the case of using data tables, solar calculations taken in real time or series of rules together with actuator positions translated from standard elevation and azimuth angles, the use of spline curves are not necessary. When using spline curves that are created by taking multiple known angular positions of the sun during the day and translating those angles into linear actuator 24, 26 positions based on the a relationship between the angular positions of the sun and the mechanical configuration of the Tracker apparatus 10. The linear actuators 24, 26 and their relative positions become data points for the creation of the spline curve which is a function of the “T” variable of time from sunrise to sunset. Additional spline curves are also used to map the angles of the linking mechanism 50 and axles 54, 56 and the time-function ratio of those angular positions and angular velocities are related to the linear positions and velocities of the actuators 24, 26. The local computer 100 located on each Tracker apparatus 100 is capable of calculating these spline curves overnight for the next day's use using previously stored data. In the case where a central computer is used to calculate the spline curves, data tables, real time solar calculations, or series of rules together with actuator positions translated from standard elevation and azimuth angles for all the Trackers apparatus 10 in a cluster 112, or scalable utility field area 114, each Tracker apparatus 10 has the ability to store a data table. Alternately, each solar tracker could be equipped with sufficiently large memory capacity to store up to several years' worth of information that is periodically downloaded from a remote operations management computer 110.

The present invention can utilize spline curve method for building the movement control system. This is because the mathematics of real-time solar calculations and their respective derivatives require much greater computational power and generates a significant error. This leads to an increase in hardware costs and reduces the accuracy and stability of the movement control system.

In a preferred embodiment, the spline curve method provides for incremental adjustments to the actuator 24, 26 velocities throughout the day with position adjustments being continuous.

The movement control system provides very accurate and smooth control for the linear actuators 24, 26. This control strategy minimizes or eliminates overdriving of the actuators 24, 26 which reduces wear and strain on the actuators 24, 26 and other mechanical components and minimizes the electrical current draw and energy use.

The linking mechanism 50 and hydraulic actuators 24, 26 are required to continuously modify the movement control system and relay this data to the local computer 100. Environment factors (temperature, wind velocity and direction), solar radiation sensor information and changes in friction adjust the hydraulic actuators 24, 26 until the actual position matches the proper position.

The main platform panel 20 in a severe weather, home stow, or night stow mode configuration 98. The severe weather, home stow, or night stow mode configuration 98 is flat and parallel to the horizontal axis.

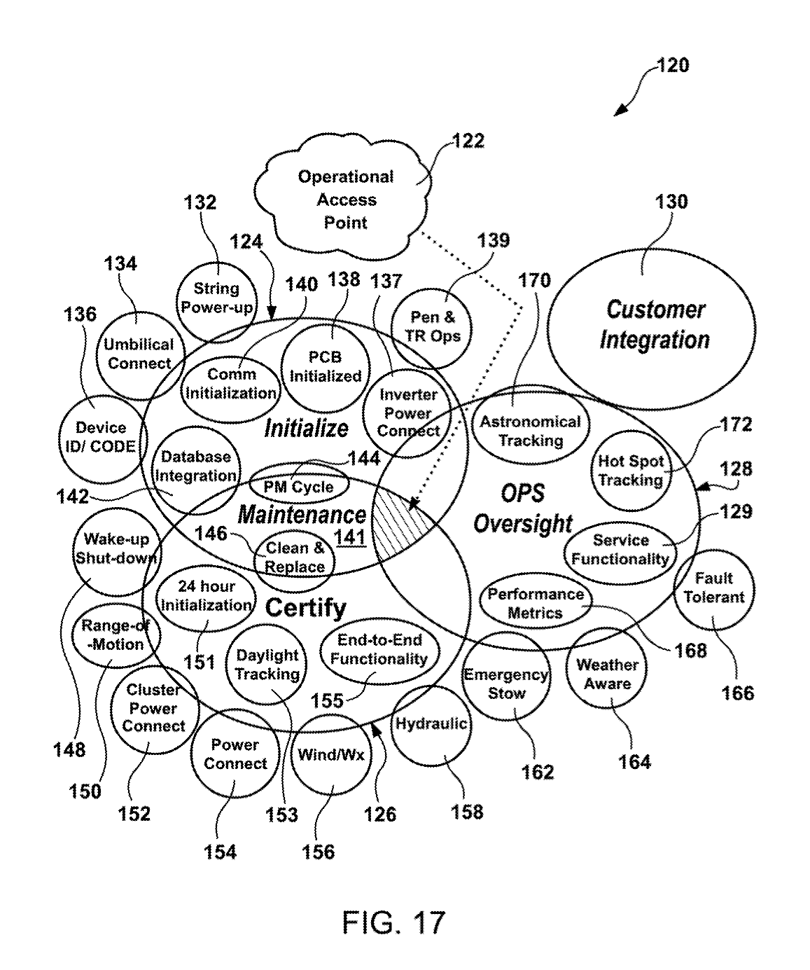

FIG. 17 is a Venn diagram graphic view of the software's operational functional modules 120, along with their respective core feature sets. The Venn diagram graphic shows all possible logical relations between finite collections of different feature sets of the software for the Track Apparatus 10. The local computer 100 or the remote operations management computer 110 will induce functional code for feature components and will communicate using the operational access point 122. During the installation process, each solar tracker apparatus 10 will undergo a certification process. If a major maintenance situation occurs, it is assumed that the Tracker will undergo a re-certify process verification stage, before returning to fully qualified service duty.

For the purpose of implementing the functional modules identified in the Venn diagram, there will be three operational modes, namely, an On-Site Control, an On-Board Control, and a Remote Access Control mode. The On-Site Control mode is utilized primarily to assist in the final assembly and erection of a single solar tracker system intended to confirm full feature functionality prior to placing system on-line for energy production. This could be a wired umbilical connection 134 providing local control over any and all operational characteristics of the solar tracker system. Once certified for full operational use, solar tracker system will switch to the On-Board Control mode where the local computer has full command of all operational characteristics. Finally, wired or wireless communication with the operational solar tracker system is achieved through the Remote Access mode.

On-Site Control mode is achieved through the use of a dedicated computer containing software instructions and coded algorithms to accomplish the task of boot-strap startup and information aggregation via these services:

Localized weather aware database informational lookups and historical table indexing, which includes the initialization and status monitoring of all sensors;

Sending over-ride response instructions as local weather conditions, range of operation, and installation startup conditions warrant;

Provide the various network administration setup and configuration routines to properly profile the wired and wireless addresses within the solar field implementation;

Provide localized view of operational performance by aggregating system into it's Cluster, Quadrant, or Block assignment as requested and required;

Provide internet testing and verification of access conduit drill-down in support of various view perspectives demanded by the Operational Management Dashboard GUI.

Remote Access control mode designates the condition where any operational movement and/or informational queries or commands, occur with wired or wireless connection(s) when not on site. Since this is now a solar tracker system in a fully functional local operation state, there is no need for anyone to perform any movement command remotely after a Tracker is formally certified. On-site personnel will initiate any specific Tracker motion command, a much safer paradigm. Therefore the software Operations Oversight (OPS) module needs only to be a web aware application.

Additionally, the Applicant may maintain the communication channel, depicted on the Venn diagram as an Operational Access Point (OAP), which will exist and will be utilize for the purpose of providing dynamic status information only. This allows for discerning root cause origin of any problem thru understanding real-time and historical performance characteristics. At a minimum, the solar tracker system is expected to provide the following when queried via this mode:

The current operation status and configuration parameters of all sensors and monitoring devices, along with their respective historical performance parameters;

The unique identification badge label such that each system can be individually or collectively grouped into performance metrics profiles.

It is deemed highly possible a more substantive information stream will flow available to this OAP portal, providing background performance monitoring for the purposes of garnering a deeper understanding of the actual operational behavior and environmental response characteristics that occur at various installed latitudes across the globe. Applicant foresees the opportunity to provide an information-as-a-service (IAAS) feature with future solar tracking system installations, both as a real-world design check validation via the creation of a real-time performance database, and in concert with a structured operational metrics package that assists or enhances the Customer's ownership experience.

The Operational Day Boundary is defined as Midnight for the formal start/end of an operational day. This will map with existing worldwide time zone definitions and astronomical conventions currently used, along with simplifying the data mining efforts toward assuming how to properly calculate a day's performance parameters.

The Production Day Boundary is defined as the time period from 5 a.m. to 9 p.m. which will be used for the formal start/end of a production day unless moonlight tracking is initiated. It will be assumed that the Tracker apparatus 10 is “out-of-service” in a Home Stow position during the hours of typical darkness. This Home Stow position is expected to be after daily solar production, beginning no later than 9 p.m., until before the start of new daily solar production, expected to begin at 5 a.m.

Shifting the data reporting to this day boundary will allow a more accurate Tracker behavior profile reporting picture of hours-out-of-service via the hours-in-service. An annual adjustment for Sun's arc path, which affects available daylight, is expected.

For Customer Grid Integration, the Customer will be required to properly understand exactly how the Grid interface “hand shake” will occur. It is possible that the Customer will require nothing more than what is planned and developed as a SCADA (Supervisory Control and Data Acquisition) compliant OPS Performance oversight functional module, utilizing their existing management control applications once the power generation is connected to their Grid.

Occasionally internet access issues to be resolved during extended service life, but Initialize/Certify/Maintenance stages don't require web based mirrored application versions. These are to be utilized in a comprehensive menu package, launched as needed dependent upon the specific stage of Tracker development encountered. Each Tracker apparatus 10 certifies a specific Cluster each day or during a specific time period. The Maintenance/Certify module 126 feature set will remain functionally equivalent for any and ah field deployed Trackers apparatus 10. GUI will allow drill-down functionality into each Tracker data base utilizing MW Block naming scheme already devised. The OPS Oversight module 128 will provide base feature functionality. If two (2) or more Trackers are commissioned at this stage, additional requirements to review their operation now exist with both acting as separate 100 MW Blocks deployment for aggregated performance reporting. The OPS Oversight Module 128 will require drill-down functionality for base feature functions of a single Tracker; then aggregated performance for a Cluster, then MW Block configurations. The customer integration module 130 is only needed once the Production stage is fully implemented. Direct connection to local power Grid can occur without software oversight. Simply providing access to OPS Oversight 128 performance will suffice until final Customer Integration requirements are mutually defined. The following will provide a more detailed description of the computer modules. During the “Start-Up” procedure, the Tracker Apparatus 10 is designed to directly address the initial construction of a single tracker, examining the Tracker construction process to verify operational readiness.

As shown in FIG. 17, there are four distinct operational functional modules which interact and remain interdependent within specific configuration limits, as shown via the Venn diagram, to propel Applicant's solar tracker system from kitted parts into a fully functional solar radiation energy generator. These four modules provide the features making this invention an operationally intelligent yet environmentally aware system.

The first module, referenced as INITIALIZE MODULE 124, is designed to address the initial construction of a single tracker, and examining the Tracker construction process. Various sub-modules and software sub-routines associated with the Initialize Module 124 include PCB initialization 138, string power up 132, umbilical connect 134, Tracker device identification and coding 136, database integration 138, inverter connect 137 and Pen & TR operations 139. Verification of the initialize module 124 operational readiness via the features sets is provided below.

Base initialization of local computer's PCB from cold boot 138, which includes the need to prove active available DC power, driving a defined sequence toward power-on-self-test (POST) 132. Additional elements needed, but not limited to, will be sub-routines designed to verify the BIOS state, battery voltage levels coupled with drain current, and followed by atomic clock initialization routines that support GMT synchronizing.

Next follows critical need to determine and establish initialization of key communication components which support Wi-Fi protocols, send/receive bit transmission packet protocols, and web ‘http’ stack layers.

Device identification badge assignment is required, followed by initialization routines for database generation for pending information storage.

Launch instructions for the pan and tilt movement control sub routines commence, resulting in the ability to test base operational range-of-motion and acknowledgement of maximum tilt service failure stop.

Launch instructions for base initialization of hydraulics operations, which includes tests for operational range functionality and responsiveness.

Software instructions now test the existence of all the umbilical connections used for both power & communication links with on-site personnel.

Subroutines are initialized for the purpose of powering up, sequencing and testing the solar panel sting combiners in each of the numerous rows of panels arranged into functional strings on the planar platform.

Now initialization routines that drive the interface instructions for Inverter power connections launched and activate themselves to OEM protocols.

Initialization sequencing process will complete after successful termination of all segments above, resulting in the final verification of the Tracker's kW capacity output levels.

The second module, referenced as CERTIFY MODULE 126, is designed to directly address the need for a Day-Of-Operation performance condition prior to formally handing off ownership of a completed Tracker system. Various sub-modules and software sub-routines associated with the Certify Module 126 include wake-up and shut-down 148, range of motion 150, 24 hour initialization 151, cluster power connect 152, 3^{rd} power connect 154, wind/Wx 156, end-to-end functionality 155, and hydraulic status 158. Full power production and unattended operational compliance must be established and verified. This should be completed within 24 hours, initiated any time prior to Sunrise following either an initial construction phase or service re-introduction promotion following a maintenance cycle, to properly examine a Tracker validating its operational readiness via the following features sets:

Subroutines for triggering the standard daily Wake-up and Shut-down 148 conditions within an operational 24 hour period will be included.

Full range-of-motion 150 depicting all possible duty cycle conditions will be introduced, as these motion flex points will be tested both within an typical operational day horizon, periodically bracketed with various motion test routines to validate designed range-of-motion.

All the grid power connections 152, 154 will be examined, both for the existence of current load(s) and current flow rates bracketed by design expectations.

A full battery of operational conditions will be applied to examine the hydraulics' responsiveness 158, which will include but are not limited to, typical day range-of-motion performance curve; the emergency stow sub-routine's speed, response time, and force at conditional hand-off; sensor performance readings address viscosity levels, pressure ramp-up vs. bleed-down rate, and true hydraulic throw distance.

Testing verification of full Day-of-Operation's performance characteristics from sunrise to sunset, and all the metric data produced against design specifications with the goal to verify nominal performance curve.

Full and robust test suite that properly verifies and confirms nominal performance of the Astronomical and Hot Spot algorithms, coupled with back-tracking subroutines, as needed.

Robust testing of adverse weather conditions will include, but not limited to, the trigger, non-trigger, and threshold conditional parameters against their responsiveness curve actuals vs. acceptable time lag tables we've designed.

Aggregate actual performance characteristics for all the remaining onboard sensor's functionality and time lag responsiveness for temperature, humidity and irradiance detection.

The third module, referenced as MAINTENANCE MODULE 141, is designed to directly address the field needs of each specific Tracker. Various sub-modules and software sub-routines associated with the Maintenance Module 141 include PM cycle 144 and clean and replace 146. Operated by a single individual, via a wireless or direct umbilical connected computer, allows the performance of any required maintenance followed by engagement of any operational feature set combination itemized above, from either the INITIALIZE or CERTIFY MODULES. Tipping in any direction allows easy access to any main planar platform quadrant across all four possible axes (North, South, East or West) and will support any of the following conditions in either a preventative or event driven maintenance situation.

Standard service-life tasks for preventative maintenance (PM) duties that may need to be performed, such as but not limited to, the hydraulic actuators, operational fluid replacement, PV solar panel service or replacement, wiring loom or hub connectors, racking connections, or general cleaning.

Structural repairs and or component replacement, to include the ability to activate an electro-mechanical cut-off switch to remove Tracker from any energy grid production contribution.

Intentional action to take Tracker off-line, as conditions warrant, where the Maintenance Stow position is invoked until such time as required parts or scheduled become available to fully complete scheduled or unscheduled maintenance activities.

The fourth module, referenced as OPS (OPERATIONS) OVERSIGHT MODULE 128, is designed to directly address the daily need to functionally operate the Tracker Apparatus 10, Cluster configuration and MW Block field configurations. Various sub-modules and software sub-routines associated with the Operations Oversight Module 128 include astronomical tracking 170, hot spot tracking 172, performance metrics 160, service functionality 129, fault tolerant 166, weather and wind aware 164, and emergency stow 162. A GUI design will allow drill-down into various aggregated performance views, depending upon which functional perspective is required. Therefore the software OPs Oversight module is a web aware application.

Operational oversight may exist in the form of starting at a top-level perspective, aggregating performance information into an easily understandable presentation, followed by subsequent drill down perspectives to reveal more finite operational groupings (clustering) to improve discrete identification of specific performance behaviors. This could take the form of high level color coded status flags, signaling the various operational states currently implemented. Examples, but not limited to, could occur if an extended Maintenance situation is active, or if emergency stow actions are underway, or energy performance curves are being effected by current weather conditions.

This last identified module, depicted as adjacent to the OPS OVERSIGHT MODULE, is defined to be Customer Integration which—is designed to directly address the situation where the Customer wants 100 MW Block performance data, provided either as structured data packets or data on-demand (via system hooks), into the OPS Oversight module, a SCADA compliant application. Direct mating to the Customer's existing grid management application(s) will be provided via SCADA protocols. Lower level direct mating from inverters coupled to Customer's transformer will also be possible, when information conditions warrant. These direct mate informational requirements in no way prevent the Customer from using the Ops Oversight module as a secondary, stand-alone performance monitoring solution.

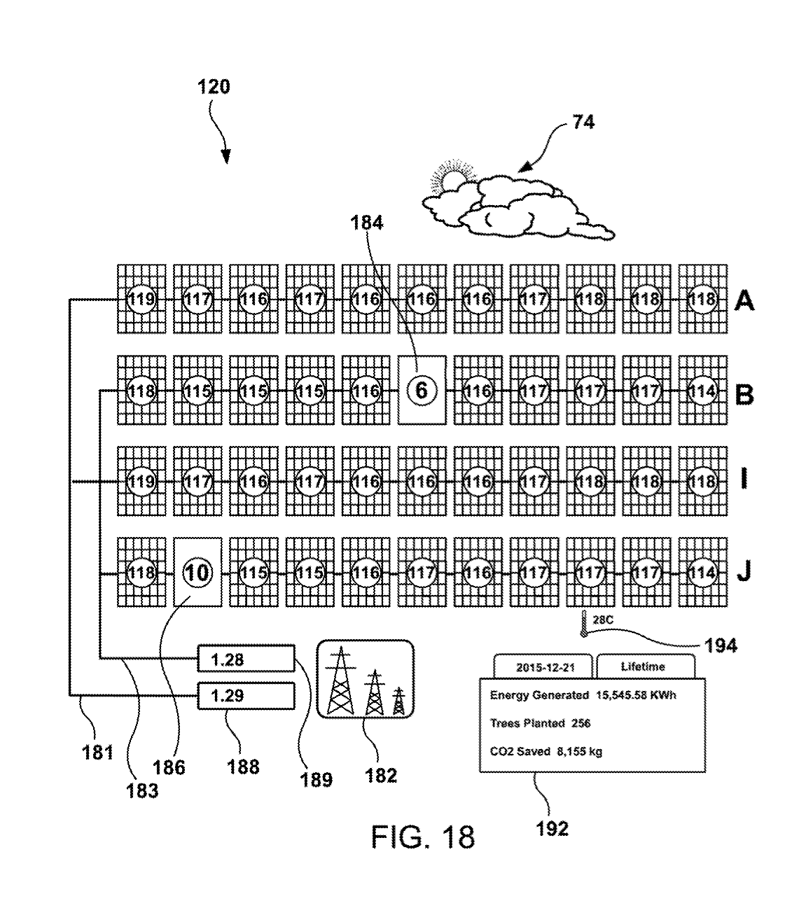

FIG. 18 is perspective graphical user view (GUI) of the plurality of Trackers that result in a 100 mega-watt [BLOCK VIEW] energy production. This figure is exemplary and it is anticipated by the Applicant that more or less tracker apparatuses can be used for energy production. Shown in this Figure are an exemplary of forty-four tracker apparatuses 10 arranged so each tracker apparatus 10 is electrically coupled to each other. It is anticipated by the Applicant that the large utility field will include approximately 1,000 Tracker apparatuses 10 comprising a large block utility scaled field designed to produce approximately a gross power capacity of 100 megawatts, and approximately 4,000 Tracker apparatuses comprising a large square utility scaled field, designed to produce a gross power capacity of approximately 400 Megawatts. The system is arranged so each tracker apparatus 10 has a unique, defined identification number. The plurality of tracker apparatuses 10 are electrically coupled to a utility scaled electric grid. Selecting any numbered Tracker apparatuses icon will cause a drill-down experience to reveal a detailed view and related performance characteristics of that cluster.

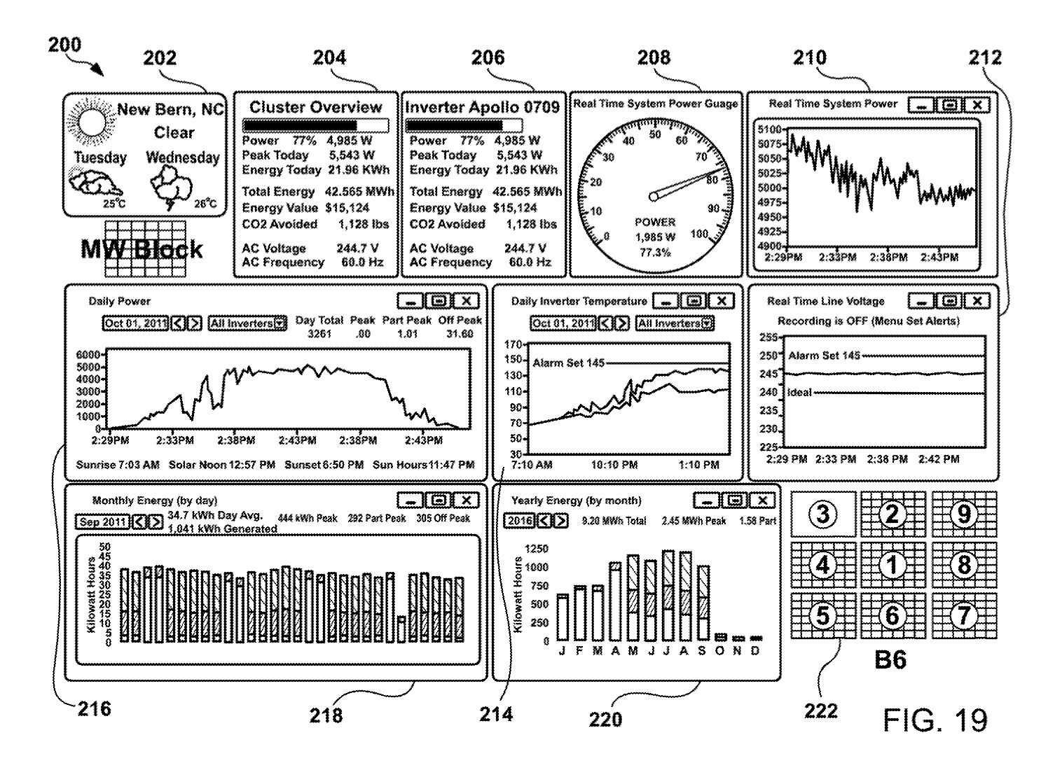

FIG. 19 is a perspective GUI view [CLUSTER VIEW] of the Tracker Operations Management Dashboard 180 having a 1 Megawatt (the output of a cluster is 115 kW×9=1.035 MW) view of Tracker monitoring of electrical parameters. A cluster design is a function of selected Inverter capacity, currently thought to be supporting nine (or a range of 7-12) tracker apparatuses placed near each other in a specific pre-determined manner to eliminate or mitigate shadow casting between tracker apparatuses with each tracker output feeding into one (1) common inverter thereby allowing the cluster to work as a unit. In this exemplary view, the output of the cluster is 1.035 Megawatts. In this dashboard GUI view, shown is a weather pane 182, a cluster overview pane 184, a real-time power gauge pane 186, a real time system pane 188, daily power graph pane 190, real time line voltage pane 192, a daily energy over a month period pane 194, a monthly energy, over a year period, pane 196, and a graphic depiction of the cluster trackers apparatus 200. This figure is exemplary and it is anticipated by the Applicant that more or less panes can be used for comprehensive performance oversight in a cluster view. Additionally, there is depicted a drill-down (lower right corner) and drill-up (upper left corner) panes assisting the ability to drill-down to a specific Tracker perspective, or drill-up to the parent Mega-Watt Block view. Furthermore, the exemplary figure can include additional panes or replace some of the existing shown panes. It is also anticipated by the Applicant that the panes of this GUI view Dashboard can be customized by the user.

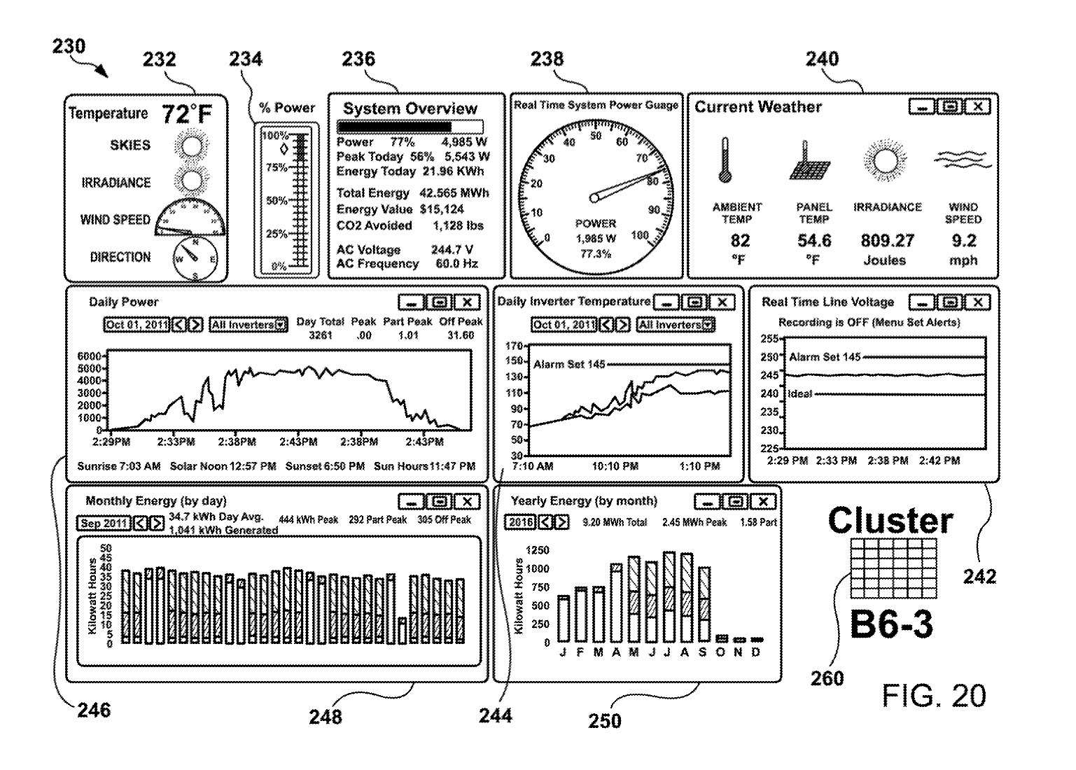

FIG. 20 is a perspective GUI view [SINGLE VIEW] of the Tracker Operations Management Dashboard 230 having a 100 kilowatt single view of Tracker monitoring elements of electrical In this exemplary dashboard view, shown is a weather pane 232, a % power pane 234, a system overview pane 236, a real-time system power gauge pane 238, a current weather pane 240, daily power graph pane 246, daily inverter temperature pane 244, real time line voltage pane 242, a daily energy over a month period pane 248, a monthly energy, over a year period, pane 250, and a graphic depiction of the cluster trackers apparatus 260. This specific pane assists in the ability to quickly drill-up to the parent Cluster view. This figure is exemplary and it is anticipated by the Applicant that more or less panes can be used for this GUI view. Furthermore, the exemplary figure can include additional panes or replace some of the existing shown panes. It is also anticipated by the Applicant that the panes of this cluster view Dashboard can be customized by the user.

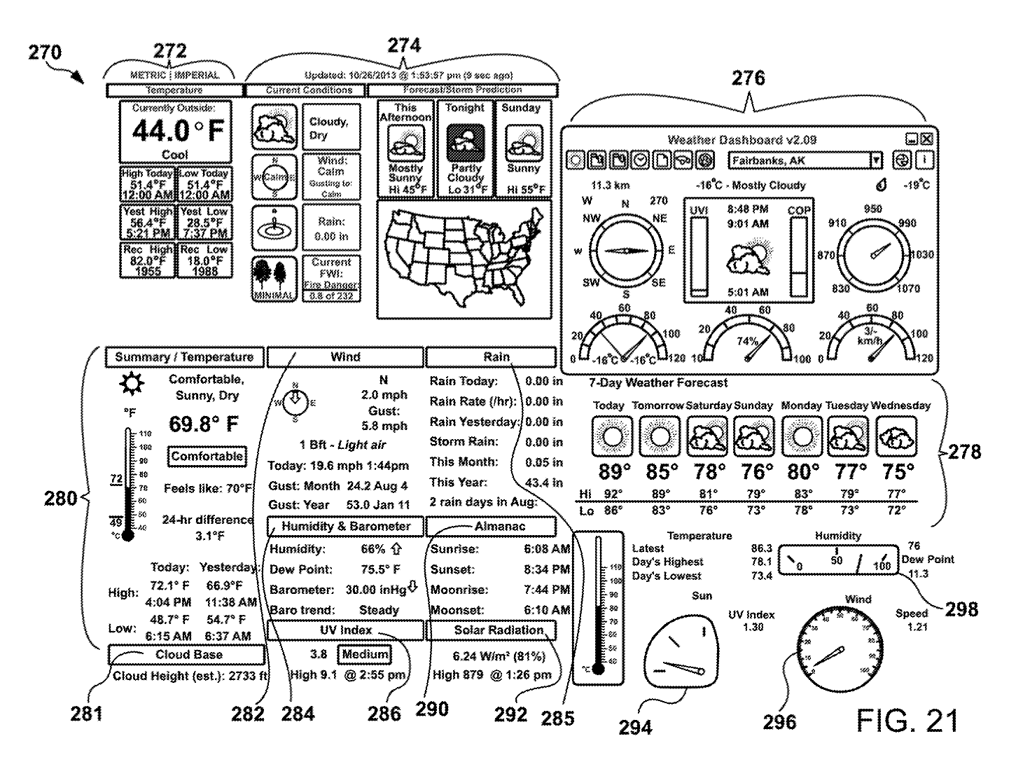

FIG. 21 is a perspective GUI view [ENVIRONMENTAL VIEW] of the Tracker Operations Management Dashboard 270 showing the tracking of critical environmental variables. Shown in this figure is a current weather pane with current temperature with daily high temperature, low temperature, record high and low temperature pane 272, and center pane having the cloud conditions 274, wind conditions 282, rain conditions 285, and current humidity and barometric pressure 284, UV index pane 286 Almanac pane 290, and solar radiation pane 29. The left side pane shows the temperature summary 280 and a cloud base pane 281. The right side panel show a weather dashboard pane 276 and shows the 7 day weather forecast 278. At the lower right panes are a graphical representation of the sun radiation energy 294, wind direction 296 and humidity 298. This figure is exemplary and it is anticipated by the Applicant that more or less panes can be used for this GUI view. Furthermore, the exemplary figure can include additional panes or replace some of the existing shown panes. It is also anticipated by the Applicant that the panes of this environmental view Dashboard can be customized by the user.

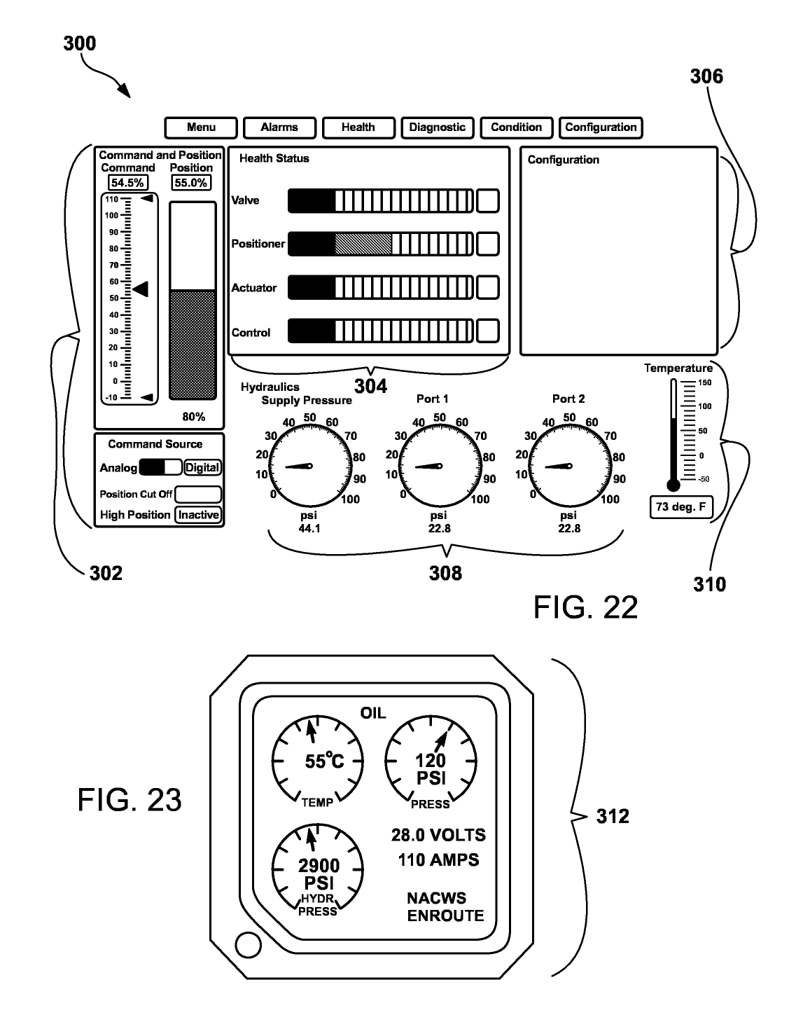

FIG. 22 is a perspective GUI view [HYDRAULICS VIEW] of the Tracker Operations Management Dashboard 300 showing the tracking of critical hydraulic variables. Shown in the left pane is a graphical representation of the lubricant temperature, hydraulic actuator pressure, and has soft buttons for command sources. Along the top are a series of soft buttons for monitoring and adjusting conditions, e.g. menu, alarms, health, diagnostic, condition, configuration. The center pane 304 demonstrates the hydraulic actuator health status 304, showing valve, positioner, actuator, and control variables. A temperature gauge 310 is shown on the right side and the lower panes show the hydraulic supply pressure 308 for overall, port 1 and port 2.

FIG. 23 is a perspective view of the Tracker Apparatus Management Dashboard GUI 312 showing the monitoring of critical hydraulic oil variables. Shown monitored is the temperature, pressure, hydraulic pressure, and volts and amp for the electric system. This figure is exemplary and it is anticipated by the Applicant that more or less panes can be used for this GUI view. Furthermore, the exemplary figure can include additional panes or replace some of the existing shown panes. It is also anticipated by the Applicant that the panes of this environmental view Dashboard can be customized by the user.

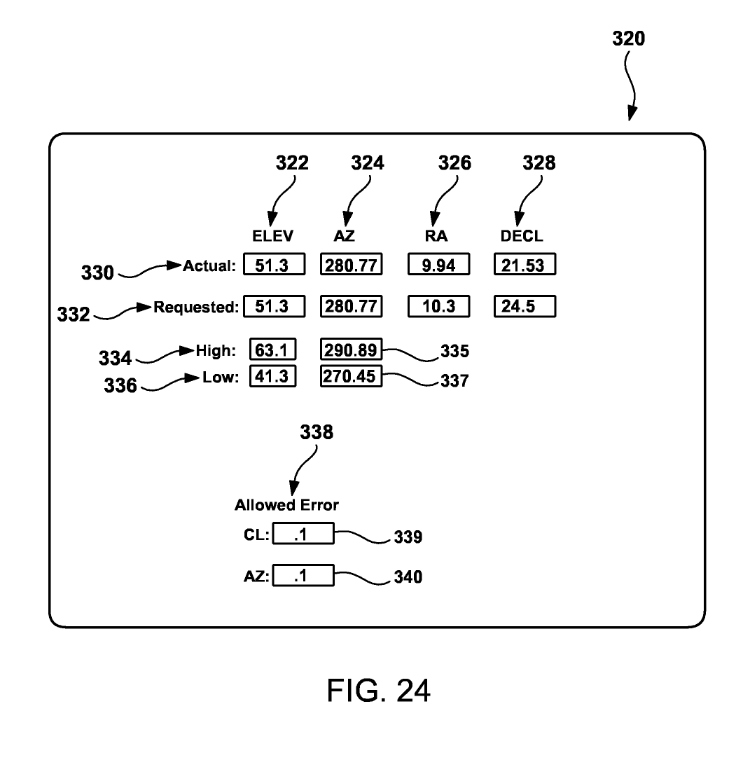

FIG. 24 is a perspective view of the Tracker Apparatus Management Dashboard GUI showing the precise monitoring of the main platforms position 320. Shown in this pane 320 pane is the position of the hydraulic actuator 270 in elevation 322, azimuth 324, Right Ascension (RA) 326 and Declination (DECL) 328. The bottom left pane show 338 allowable error parameters CL 339 and AZ 340. This figure is exemplary and it is anticipated by the Applicant that more or less panes can be used for this GUI view. Furthermore, the exemplary figure can include additional panes or replace some of the existing shown panes. It is also anticipated by the Applicant that the panes of this environmental view Dashboard can be customized by the user.

1) A solar tracker system comprising:
a foundation system;
said foundation system partially comprised of one of more pole structures, said pole structures angled such that said pole structures proximally end in a apex section;
a main platform for affixing a plurality of solar cell panels;
a sub-platform, said sub-platform having an first engagement means attached to said main platform and a second engagement means attached to a linking mechanism;
said linking mechanism that connects the sub-platform to said apex section, wherein the linking mechanism includes a first axle, a second axle and a body member disposed between the first axle and the second axle, wherein the first axle and the second axle are disposed substantially orthogonal to each other;
at least two linear actuators, each actuator having a first end and a second end; a rotational joint for connecting the second end of the linear actuators to the a driver system for driving the linear actuators;
a control system including a local computer that calculates desired positions of the linear actuators using a digital compass, digital inclinometers, and multiple points as modifying inputs and communicates with the driver system to drive the linear actuators to the desired positions;
one or more solar radiation sensors, said one or more solar radiation sensors located in close proximity to said solar cell panels, said one or more solar radiation sensors in electronic communication with said local computer using environment points as modifying inputs and communicates with said computer;
a local weather station, said local weather station located in close proximity to said solar cell panels, said local weather station having the capacity to monitor the wind velocity and directions, said local weather station in electronic communication with said computer using environment points as inputs; and said local computer in wireless or wired communication with a remote operations management computer for monitoring said system variables and regulate said system controls.

2) The solar tracking system as recited in claim 1, further comprising a rotational joint for connecting the first end of the linear actuators to a foundation system.

3) The solar tracking system as recited in claim 1, wherein said local computer can download weather data from the internet or satellite source.

4) The solar tracking system as recited in claim 1, wherein said linking system is fabricated from a metallic or concrete material, and wherein said first axle and second axle are fabricated from a metallic material.

5) The solar tracking system as recited in claim 1, wherein the ends of the first axle and the second axle are disposed in bronze bearing assemblies.

6) The solar tracking system as recited in claim 1, wherein said foundation system including a plurality of beams and a plurality of securing members.

7) The solar tracking system as recited in claim 6, wherein said foundation is fabricated from A588 steel or Series 300 stainless steel, or any combinations thereof.

8) The solar tracking system as recited in claim 1, wherein the rotational joint and the linking member include two degrees of freedom rotational movement.

9) The e solar tracking system as recited in claim 1, wherein said linear actuators utilize a hydraulic system.

10) The solar tracking system as recited in claim 8, wherein a hydraulic system includes a reservoir, an external electric motor and an internal hydraulic pump that are in close proximity to the one or more support tubes or the main platform.

11) The solar tracking system as recited in claim 9, wherein the linear actuators are hydraulic cylinders, the driver system is an electric motor connected to a hydraulic pump, and the movement control system communicates with the electric motor and a series of valves in the system to move the sub-platform to desired positions.

12) The solar tracking system as recited in claim 10, further comprising that said hydraulic linear actuators include a pressure sensor, said pressure sensor in electronic communication with said local computer.

13) The solar tracking system as recited in claim 1, further comprising means for preventing the main platform from being driven past its mechanical limits.

14) The solar tracking system as recited in claim 1, wherein the data points are calculated in real-time.

15) The solar tracking system as recited in claim 1, wherein the multiple points include time of day, date of month and year, geographical positioning system coordinates, foundation orientation, cylinder positions, the linking member's angles, solar radiation sensor data and environmental variables.

16) The solar tracking system as recited in claim 1, wherein said remote computer can communicate with said remote operations management computer anywhere in the world.

17) The solar tracking system as recited in claim 1, further comprising a mounting system that facilitates the replacement of poor performing, or defective solar cell panels.

18) The solar tracking system as recited in claim 1, whereas said main platform is angled and positioned in a maximum solar efficiency configuration upon monitoring environmental conditions.

19) The solar tracking system as recited in claim 1, whereas said main platform is angled and positioned in a wind avoidance configuration upon the occurrence of certain environmental conditions.

20) The solar tracking system as recited in claim 1, whereas said main platform is angled and positioned in a rain cleaning configuration upon the occurrence of certain environmental conditions.

21) The solar tracking system as recited in claim 1, whereas said main platform is angled and positioned in a stow or maintenance configuration upon the occurrence of certain extreme or repair conditions.

22) A utility scale solar tracker field comprising:
a plurality of solar trackers whereby each solar tracker includes;
a foundation system;
said foundation system partially comprised of one of more pole structures, said pole structures angled such that said pole structures proximally end in a apex section;
a main platform for affixing a plurality of solar cell panels;
a sub-platform, said sub-platform having a first engagement means attached to said main platform and a second engagement mean attached to a linking mechanism;
said linking mechanism that connects the sub-platform to said apex section, wherein the linking mechanism includes a first axle, a second axle and a body member disposed between the first axle and the second axle, wherein the first axle and the second axle are disposed substantially orthogonal to each other;
at least two linear actuators, each actuator having a first end and a second end; a rotational joint for connecting the second end of the linear actuators to the a driver system for driving the linear actuators;
a control system including a local computer that calculates desired positions of the linear actuators using a digital compass, digital inclinometers, and multiple points as modifying inputs and communicates with the driver system to drive the linear actuators to the desired positions;
one or more solar radiation sensors, said one or more solar radiation sensors located in close proximity to said solar cell panels, said one or more solar radiation sensors in electronic communication with said local computer using environment points as modifying inputs and communicates with said computer;
a local weather station, said local weather station located in close proximity to said solar cell panels, said local weather station having the capacity to monitor the wind velocity and directions, said local weather station in electronic communication with said computer using environment points as inputs and communicates;
said local computer in wireless or wired communication with a remote operations management computer for monitoring said system variables and regulating said control system; and
said plurality of solar trackers are grouped in a unique and specific Cluster design unit pattern, with each unit connected to an inverter for converting the DC electrical energy to AC electrical energy, said AC electrical energy is then connected to an electrical grid.

19) The utility scale solar tracker enterprise as recited in claim 22, where the accumulation of additional Clusters is scalable.

20) The utility scale solar tracker enterprise as recited in claim 22, wherein said plurality of solar trackers grouped in Clusters includes 1000 or more tracker apparatuses representing a Block.

21) The utility scale solar tracker enterprise as recited in claim 22, wherein said 1000 or more tracker apparatus provide has a gross power capacity of approximately 100 megawatts of power.

22) The utility scale solar tracker field as recited in claim 22, wherein the construction of the utility scale field is scalable.

23) The utility scale solar tracker enterprise as recited in claim 22, wherein said plurality of solar trackers grouped in Clusters includes 4000 or more tracker apparatuses representing a Square.

24) The utility scale solar tracker enterprise as recited in claim 22, wherein said 1000 or more tracker apparatus provide has a gross power capacity of approximately 400 megawatts of power.

25) The utility scale solar tracker field as recited in claim 22, wherein the construction of the utility scale field is scalable.
